(19) United States
(12) Patent Application Publication
(10) Pub. No.: US 2016/0284901 A1
(43) Pub. Date: Sep. 29, 2016

(54) METHOD OF MANUFACTURING CI(G)S-BASED THIN FILM INCLUDING AGING OF SLURRY COMPRISING BINARY NANOPARTICLES, AND CI(G)S-BASED THIN FILM MANUFACTURED THEREBY

(71) Applicant: KOREA INSTITUTE OF ENERGY RESEARCH, Daejeon (KR)

(72) Inventors: Ara CHO, Daejeon (KR); Kyung Hoon YOON, Daejeon (KR); SeJin AHN, Daejeon (KR); Jae Ho YUN, Daejeon (KR); Young Joo EO, Daejeon (KR); Jihye GWAK, Daejeon (KR); SeoungKyu AHN, Seoul (KR); Jun Sik CHO, Daejeon (KR); Jin Su YOO, Daejeon (KR); Kihwan KIM, Daejeon (KR); Joo Hyung PARK, Daejeon (KR)

(21) Appl. No.: 14/421,866

(22) PCT Filed: Aug. 30, 2013
(86) PCT No.: PCT/KR2013/007810

§ 371 Date: Feb. 16, 2016

(51) Int. Cl. H01L 31/032; C23C 14/58; H01L 31/18; H01L 31/0392

(52) U.S. Cl. CPC H01L 31/0322; H01L 31/03923; C23C 14/5866; C23C 14/5806; H01L 31/18

(57) ABSTRACT

Disclosed are a method of manufacturing a CI(G)S-based thin film including aging of a slurry composed of binary nanoparticles, and a CI(G)S-based thin film manufactured thereby. The method of manufacturing the CI(G)S-based thin film includes: preparing CI(G)S-based binary nanoparticles; mixing the binary nanoparticles, a solution precursor including a CI(G)S-based element, a solvent and a chelating agent, thus preparing a hybrid slurry; aging the hybrid slurry for 5 to 10 days; subjecting the aged hybrid slurry to coating, thus forming a CI(G)S-based thin film; and subjecting the CI(G)S-based thin film to heat treatment. Thereby, high reproducibility can be ensured upon manufacturing a CI(G)S-based thin film for solar cells, and thus reliability of the produced thin film can be increased.

### TECHNICAL FIELD

The present invention relates to a method of manufacturing a CI(G)S-based thin film for solar cells. More particularly, the present invention relates to a method of manufacturing a high-density CI(G)S-based thin film by a hybrid process using binary nanoparticles, wherein when a CI(G)S-based thin film is manufactured from a slurry comprising binary nanoparticles and a solution precursor using a non-vacuum coating process, the slurry is aged for a predetermined period of time and then applied, thereby allowing the production of a dense thin film at high reproducibility, and to a CI(G)S-based thin film manufactured by the method.

### BACKGROUND ART

Due to present serious environmental pollution problems and pending fossil energy exhaustion, the importance for the development of next-generation clean energy is increasing. In particular, solar cells are a device for directly converting solar energy into electric energy and are expected to be an energy source able to solve future energy problems because they produce low pollution, operate on the unlimited resource of sunlight and have a semi-permanent lifetime.

Solar cells are variously classified depending on the type of material used for the light absorption layer thereof. Currently mainly useful is a silicon solar cell using silicon. However, as the price for silicon solar cells has drastically increased due to the short supply of silicon, thin film-type solar cells are receiving a great attention. A thin film-type solar cell is manufactured to be slim, and thus has a wide application range because of low material consumption and light weight. Thorough research is ongoing into amorphous silicon and CdTe, CIS or CIGS as materials for thin film-type solar cells.

CIS or CIGS thin films include compound semiconductors, and exhibit the highest conversion efficiency (20.3%) among thin film solar cells made in lab. Such CIS or CIGS thin films may be manufactured to a thickness of 10 μm or less and may manifest stable properties even upon long-term use, making it possible to achieve an inexpensive high-efficiency solar cell, instead of silicon. Furthermore, a CIS thin film, which is a direct transition semiconductor, may be provided in the form of a thin film and is comparatively adapted for light conversion because it has a bandgap of 1.04 eV, and the coefficient of light absorption thereof is high among known solar cell materials. A CIGS thin film is developed by substituting a portion of In with Ga or by substituting S with Se to improve low open voltage of the CIS thin film.

A CIGS-based solar cell is manufactured in the form of a thin film having a thickness corresponding to ones of μm, and the manufacturing method thereof largely includes a vacuum deposition process, and a non-vacuum process including applying a precursor material and then performing heat treatment. Specifically, a vacuum deposition process is advantageous because an absorption layer having high efficiency may be manufactured, but it is difficult to uniformly form a large-area absorption layer and expensive equipment has to be used. Furthermore, 20˜50% of the material used may be lost, undesirably increasing the manufacturing cost. On the other hand, a non-vacuum process including applying a precursor material and then performing heat treatment at high temperature may exhibit low manufacturing cost and enable a large-area layer to be uniformly formed, but the efficiency of the absorption layer is comparatively low.

For non-vacuum fabrication of a thin film for a CIGS-based solar cell, it is very important to improve light absorption efficiency of the thin film and to ensure high reproducibility for mass production. In regard to the light absorption efficiency of the thin film, a filling element is interposed in the pores between CIS-based compound nanopowder particles and then thermally treated, which is disclosed in Korean Patent No. 10-1129194. Also in order to ensure reliability of a thin film, Korean Patent Application Publication No. 10-2009-0043265 discloses a method of manufacturing a thin film that includes coating ternary or quaternary nanoparticles, in lieu of the binary nanoparticles, with a surfactant, applying such particles on a substrate, and removing the surfactant. However, the surfactant used has to be removed using a removal process, and such a removal process makes it difficult to ensure high reproducibility.

Among thin films for solar cells variously manufactured reported to date, a CIGS thin film formed by applying a solution precursor material in a non-vacuum has many pores and is not dense, and is difficult to reproducibly manufacture.

### DISCLOSURE

### Technical Problem

Accordingly, an object of the present invention is to provide a method of manufacturing a CIGS-based thin film for solar cells by means of a hybrid concept of a process for using CIS or CIGS nanoparticles and a process for using a solution precursor, wherein the thin film is made dense via non-crystalline growth of particles and minimization of impurities, thus improving efficiency and also ensuring high reproducibility.

### Technical Solution

In order to accomplish the above object, the present invention adopts a hybrid process using a hybrid slurry prepared by mixing CI(G)S-based binary nanoparticles, a solution precursor including a CI(G)S-based element, a solvent, and a chelating agent, and thereby a dense thin film may be obtained, and also, the hybrid slurry is aged for 5 to 10 days before being applied on a substrate, thereby ensuring high reproducibility.

Specifically, the present invention provides a method of manufacturing a CI(G)S-based thin film by a hybrid process using binary nanoparticles, comprising: (a) preparing CI(G)S-based binary nanoparticles; (b) mixing the binary nanoparticles, a solution precursor including a CI(G)S-based element, a solvent and a chelating agent, thus preparing a hybrid slurry; (c) aging the hybrid slurry for 5 to 10 days; (d) subjecting the aged hybrid slurry to non-vacuum coating, thus forming a CI(G)S-based thin film; and (e) subjecting the CI(G)S-based thin film to selenization heat treatment.

In a preferred embodiment of the present invention, the binary nanoparticles comprise any one selected from the group consisting of Cu—Se, In—Se, Ga—Se, Cu—S, In—S, and Ga—S.

In the method, (a) may be performed using any one process selected from the group consisting of a low-temperature colloidal process, a solvothermal synthesis process, a microwave process, and an ultrasonic synthesis process.

The solution precursor may include at least one CI(G)S-based single element that is not contained in the binary nanoparticles.

The solvent may be an alcoholic solvent.

The alcoholic solvent may be any one selected from the group consisting of ethanol, methanol, pentanol, propanol, and butanol.

The chelating agent may be any one selected from the group consisting of monoethanolamine (MEA), diethanolamine (DEA), triethanolamine (TEA), ethylenediamine, ethylenediamine acetic acid (EDTA), nitrilotriacetic acid (NTA), hydroxyethylenediamine triacetic acid (HEDTA), glycol-bis(2-aminoethylether)-N,N,N′,N′-tetraacetic acid (GEDTA), triethylenetetramine hexaacetic acid (TTHA), hydroxyethyl iminodiacetic acid (HIDA), and dihydroxyethyl glycine (DHEG).

In the method, (b) may further comprise performing sonication so that slurry components are mixed and dispersed.

Also, (c) may further comprise performing sonication during aging.

The non-vacuum coating in (d) may be performed using any one process selected from the group consisting of a spraying process, an ultrasonic spraying process, a spin coating process, a doctor blading process, a screen printing process, and an inkjet printing process.

In the method, (d) may further comprise performing drying, after coating.

Also, the coating and drying in (d) may be sequentially repeated and performed a plurality of times.

Also, (e) may be performed at a substrate temperature of 500˜530° C. for 30˜60 min.

In addition, the present invention provides a CI(G)S-based thin film for use in a light absorption layer of a solar cell, as a CI(G)S-based thin film using binary nanoparticles, wherein the CI(G)S-based thin film is manufactured by subjecting a hybrid slurry comprising CI(G)S-based binary nanoparticles and a solution precursor including at least one CI(G)S-based single element to aging for 5 to 10 days and then non-vacuum coating.

In addition, the present invention provides a solar cell using a CI(G)S-based thin film as a light absorption layer, wherein the CI(G)S-based thin film is manufactured by subjecting a hybrid slurry comprising CI(G)S-based binary nanoparticles and a solution precursor including at least one CI(G)S-based single element to aging for 5 to 10 days and then non-vacuum coating.

### Advantageous Effects

According to the present invention, a slurry comprising binary nanoparticles and a solution precursor is aged for 5 to 10 days before a coating process. Thereby, it is possible to ensure high reproducibility upon manufacturing a CI(G)S-based thin film, and thus reliability of the produced thin film can be increased.

In addition, the slurry comprising binary nanoparticles and a solution precursor is subjected to a non-vacuum coating process, thereby minimizing impurities to thus reduce pores, and improving the growth of particles to thus form a dense thin film structure. Ultimately, when such a thin film is used as a light absorption layer of a thin film solar cell, the efficiency of the thin film solar cell can be enhanced.

### DESCRIPTION OF DRAWINGS

FIG. 1 illustrates a scanning electron microscope (SEM) image of the surface of a CIS-based thin film manufactured in Example 1 according to the present invention; and

FIG. 2 illustrates an efficiency curve of a solar cell using the CIS-based thin film of Example 1.

### MODE FOR INVENTION

Hereinafter, a detailed description will be given of a method of manufacturing a CI(G)S-based thin film according to the present invention.

As used herein, the CI(G)S-based thin film refers to a CIS- or CIGS-based thin film.

According to the present invention, a method of manufacturing a CI(G)S-based thin film comprises: preparing a slurry comprising CI(G)S-based binary nanoparticles and a solution precursor, and subjecting the slurry to non-vacuum coating and heat treatment, thus forming a dense CI(G)S-based thin film. This method is specified below.

First, CI(G)S-based binary nanoparticles are prepared (Step a).

The binary nanoparticles indicate nanoparticles composed of two components among elements of IB-IIIA-VIA compound semiconductors. Examples of the binary nanoparticles may include Cu—Se, In—Se, Ga—Se, Cu—S, In—S, and Ga—S. More specifically, Cu—Se may be CuSe, Cu₂Se or Cu₂₋ₓSe (0<x<1); In—Se may be In₂Se₃; Ga—Se may be Ga₂Se₃; Cu—S may be CuS or Cu₂₋ₓS (0<x<1); In—S may be InS or In₂S₃; and Ga—S may GaS or Ga₂S₃.

Such binary nanoparticles may be prepared using any process known in the art to which the present invention belongs, such as a low-temperature colloidal process, a solvothermal synthesis process, a microwave process, or an ultrasonic synthesis process.

Next, a hybrid slurry comprising the binary nanoparticles and a solution precursor is prepared (Step b).

The slurry is prepared by mixing the CIS-based binary nanoparticles prepared in Step a, a precursor solution, a solvent, and a chelating agent.

The solution precursor indicates a solution including an element for forming a CIS or CIGS thin film, and is prepared using an element that is not contained in the binary nanoparticles, so as to be adapted for a composition ratio of the CIS or CIGS thin film. When the nanoparticles comprise Cu—Se, the solution precursor is prepared by dissolving an In precursor as a chloride or an acetate in a chelating agent, and then mixed with the nanoparticles, giving the slurry.

The solvent may include an alcoholic solvent, such as methanol, ethanol, pentanol, propanol, and butanol.

The chelating agent is viscous, and thus may functions as a binder. In order to use the binary nanoparticles together with the solution precursor, the chelating agent has to be used so that the nanoparticles and the metal ions are linked, and thereby the thin film is made dense and smooth. The amount of the chelating agent in the slurry is set to a molar amount that enables the chelating of the solution precursor.

Examples of the chelating agent may include MEA (monoethanolamine), DEA (diethanolamine), TEA (triethanolamine), ethylenediamine, EDTA (ethylenediaminetetraacetic acid), NTA (nitrilotriacetic acid), HEDTA (hydroxyethyl ethylenediamine triacetic acid), GEDTA (glycol ether diamine tetraacetic acid), TTHA (triethylenetetramine hexaacetic acid), HIDA (hydroxyethyl iminodiacetic acid), and DHEG (dihydroxyethyl glycine).

However, the present invention is not limited thereto, and any chelating agent may be used within the scope of the present invention so long as it is a ligand that chelates the metal ions and the nanoparticles for a CI(G)S-based thin film to form a compound.

As such, the concentration of the slurry may be controlled by adjusting the amount of the CI(G)S-based compound nanoparticles, and the amount of the chelating agent may be adjusted to control the viscosity of the slurry and the extent of chelating.

The slurry may undergo sonication for dispersion and mixing.

Next, the hybrid slurry is aged for 5 to 10 days (Step c).

Before a coating process of a substrate, aging the hybrid slurry is regarded as very important in the present invention. When the hybrid slurry is aged and then applied in this way, the Cu/In ratio and the thin film thickness, which are closely related with the solar light absorption efficiency of the thin film, may be optimized. Also, high reproducibility may be obtained even after several repeated tests.

According to the present invention, in Step c aging is performed for 5 to 10 days, and preferably 7 days. If the aging time is shorter than 5 days, the Cu/In ratio is considerably lower than 0.9 corresponding to the highest efficiency. In contrast, if the aging time is longer than 10 days, the total process time may be prolonged undesirably.

Preferably, sonication is further performed during the aging process. When sonication is carried out in this way, effective dispersion of the particles in the slurry may be achieved.

Next, the hybrid slurry is applied via non-vacuum coating on the substrate, thus forming a CI(G)S-based thin film (Step d).

In the present invention, forming the CI(G)S-based thin film is implemented via non-vacuum coating. Non-vacuum coating is carried out using any process well known in the art to which the present invention belongs, such as spraying, ultrasonic spraying, spin coating, doctor blading, screen printing, and inkjet printing. When such a non-vacuum coating process is applied in this way, the manufacturing cost may be decreased.

After the coating process, a drying process is performed, thereby removing the solvent.

The non-vacuum coating and drying procedures may be repeated, giving a CI(G)S-based thin film having a desired thickness. As such, the number of repeated procedures may vary as necessary, but may be set to 2 or 3.

Finally, the CI(G)S-based thin film formed in Step d is subjected to selenization heat treatment (Step e).

Selenization heat treatment, which is essential in a non-vacuum coating process, may be performed in such a manner that the temperature of the substrate having the thin film thereon is increased while supplying Se vapor formed by evaporating Se solid by heat. Thereby, the precursor thin film subjected to Step d is selenized, and simultaneously, the structure in the thin film is finally made dense, thus completing a CI(G)S-based thin film.

Preferably, this step is carried out at a substrate temperature of 500˜530° C. for 30˜60 min.

In addition, the present invention addresses a CI(G)S-based thin film manufactured by the above method.

In addition, the present invention addresses a solar cell including the CI(G)S-based thin film as a light absorption layer.

Below is a description of preferred embodiments of the present invention.

### EXAMPLE 1

In a glove box, 0.286 g of CuI was mixed with 30 mL of a distilled pyridine solvent, and the resulting mixture was mixed with 0.094 g of Na₂Se dissolved in 20 mL of distilled methanol. As such, the atomic ratio of Cu to Se was 2:1. Thereafter, while the methanol/pyridine mixture was mechanically stirred in an ice bath at 0° C., it was allowed to react for 7 min, thus synthesizing a colloid including Cu—Se nanoparticles. The colloid was centrifuged at 10,000 rpm for about 10 min, sonicated for 1 min and then washed with distilled methanol. These procedures were repeated to completely remove byproducts and pyridine from the product, thus synthesizing Cu—Se binary nanoparticles having high purity.

Subsequently, 0.2543 g of the Cu—Se nanoparticles, 0.5508 g of indium acetate, 0.3406 g of monoethanolamine as a chelating agent, and 1.4008 g of methanol as a solvent were mixed and sonicated for 60 min, thus preparing a CIS-based hybrid slurry.

As such, the atomic ratio of Cu—Se binary nanoparticles to indium acetate was maintained at 1:3, and the atomic ratio of indium acetate to chelating agent was maintained at 1:3. The amount of added methanol was adjusted so as to be adapted for desired viscosity.

Subsequently, the prepared hybrid slurry was aged for 7 days. The aged hybrid slurry was applied via spin coating on a sodalime glass substrate having a Mo thin film deposited thereon. As such, the glass substrate was rotated at 800 rpm for 20 sec. After the coating process, three-step drying was performed on a hot plate. Specifically, first drying at 80° C. for 5 min, second drying at 120° C. for 5 min and third drying at 200° C. for 5 min were carried out. Such coating and drying procedures were repeated three times, thereby forming a precursor thin film having a predetermined thickness.

Finally, selenization heat treatment was performed for 60 min while supplying Se vapor at a substrate temperature of 530° C., yielding a CIS-based thin film.

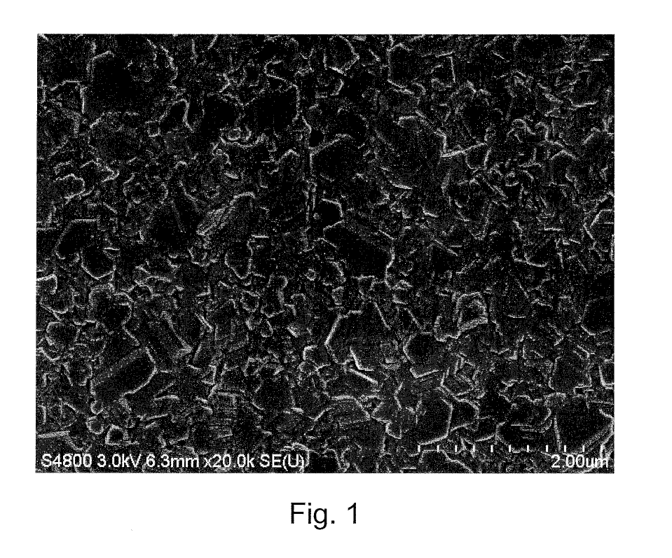

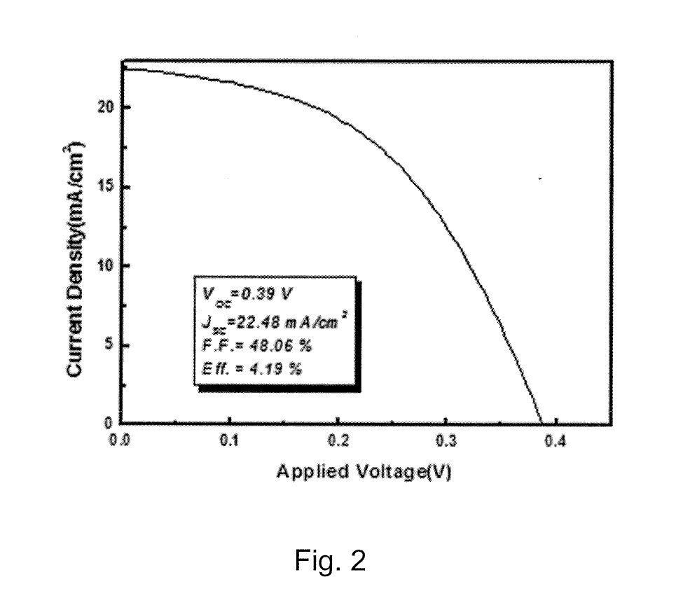

The SEM image of the surface of the CIS-based thin film of Example 1 is illustrated in FIG. 1, and the efficiency curve of the solar cell using the CIS-based thin film of Example 1 is illustrated in FIG. 2. As illustrated in FIG. 1, the CIS-based thin film according to the embodiment of the present invention exhibited effective growth of the particles, and had high density and almost no pores.

### EXAMPLES 2 AND 3

CIS-based thin films were manufactured in the same manner as in Example 1, in order to compare the reproducibility results.

### EXAMPLE 4

A CIS-based thin film was manufactured in the same manner as in Example 1, with the exception that the aging was performed for 5 days.

### EXAMPLE 5

A CIS-based thin film was manufactured in the same manner as in Example 4, in order to compare the reproducibility results.

### COMPARATIVE EXAMPLE 1

A CIS-based thin film was manufactured in the same manner as in Example 1, with the exception that the aging was performed for 3 days.

### COMPARATIVE EXAMPLE 2

A CIS-based thin film was manufactured in the same manner as in Comparative Example 1, in order to compare the reproducibility results.

### COMPARATIVE EXAMPLE 3

A CIS-based thin film was manufactured in the same manner as in Example 1, with the exception that the hybrid slurry was directly applied on the substrate without performing the aging process.

### COMPARATIVE EXAMPLE 4

A CIS-based thin film was manufactured in the same manner as in Comparative Example 3, in order to compare the reproducibility results.

The conditions and the results of Examples 1 to 5 and Comparative Examples 1 to 4 are shown in Table 1 below.

TABLE 1

| | Thin film | | | Conditions | |
|---|---|---|---|---|---|
| | thick. | | Efficiency | | Aging time |
| | (μm) | Cu/In | (%) | Cu₂₋ₓSe:In(Ac)₃ | (days) |
| Ex. 1 | 1.21 | 0.586 | 4.19 | 1:3 | 7 |
| Ex. 2 | 1.19 | 0.512 | 3.787 | 1:3 | 7 |
| Ex. 3 | 1.10 | 0.492 | 3.325 | 1:3 | 7 |
| Ex. 4 | 0.966 | 0.445 | 3.292 | 1:3 | 5 |
| Ex. 5 | 0.898 | 0.400 | 3.195 | 1:3 | 5 |
| C. Ex. 1 | 0.847 | 0.370 | 2.715 | 1:3 | 3 |
| C. Ex. 2 | 0.778 | 0.370 | 2.614 | 1:3 | 3 |
| C. Ex. 3 | 0.607 | 0.296 | 1.511 | 1:3 | 0 |
| C. Ex. 4 | 0.065 | 0.284 | 1.305 | 1:3 | 0 |

Generally, when the Cu/In ratio is close to 0.9 and the thin film has a thickness of about 1.5˜2.0 μm, the efficiency of a solar light absorption layer is known to be optimal. As is apparent from Table 1, high reproducibility was proven based on the results of Examples 1 to 3, and 4 and 5 including the aging process. When the aging time was 7 days (Examples 1 to 3) and 5 days (Examples 4 and 5), the efficiency of the prepared thin film was higher than when the aging time was 3 days (Comparative Examples 1 and 2) and 0 days (Comparative Examples 3 and 4).

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Therefore, it will be understood that the scope of the present invention is determined not by specific embodiments but by the following claims.

1. A method of manufacturing a CI(G)S-based thin film, comprising:
(a) preparing CI(G)S-based binary nanoparticles;
(b) mixing the binary nanoparticles, a solution precursor including a CI(G)S-based element, a solvent and a chelating agent, thus preparing a hybrid slurry;
(c) aging the hybrid slurry for 5 to 10 days;
(d) subjecting the aged hybrid slurry to non-vacuum coating, thus forming a CI(G)S-based thin film; and
(e) subjecting the CI(G)S-based thin film to selenization heat treatment.

2. The method of claim 1, wherein the binary nanoparticles comprise any one selected from the group consisting of Cu—Se, In—Se, Ga—Se, Cu—S, In—S, and Ga—S.

3. The method of claim 1, wherein (a) is performed using any one process selected from the group consisting of a low-temperature colloidal process, a solvothermal synthesis process, a microwave process, and an ultrasonic synthesis process.

4. The method of claim 1, wherein the solution precursor includes at least one CI(G)S-based single element that is not contained in the binary nanoparticles.

5. The method of claim 1, wherein the solvent is an alcoholic solvent.

6. The method of claim 5, wherein the alcoholic solvent is any one selected from the group consisting of ethanol, methanol, pentanol, propanol, and butanol.

7. The method of claim 1, wherein the chelating agent is any one selected from the group consisting of monoethanolamine (MEA), diethanolamine (DEA), triethanolamine (TEA), ethylenediamine, ethylenediamine acetic acid (EDTA), nitrilotriacetic acid (NTA), hydroxyethylenediamine triacetic acid (HEDTA), glycol-bis(2-aminoethylether)-N,N,N′,N′-tetraacetic acid (GEDTA), triethylenetetramine hexaacetic acid (TTHA), hydroxyethyl iminodiacetic acid (HIDA), and dihydroxyethyl glycine (DHEG).

8. The method of claim 1, wherein (b) further comprises performing sonication so that slurry components are mixed and dispersed.

9. The method of claim 1, wherein (c) further comprises performing sonication during aging.

10. The method of claim 1, wherein the non-vacuum coating in (d) is performed using any one process selected from the group consisting of a spraying process, an ultrasonic spraying process, a spin coating process, a doctor blading process, a screen printing process, and an inkjet printing process.

11. The method of claim 1, wherein (d) further comprises performing drying, after coating.

12. The method of claim 11, wherein the coating and drying in (d) are sequentially repeated and performed a plurality of times.

13. The method of claim 1, wherein (e) is performed at a substrate temperature of 500˜530° C. for 30˜60 min.

14. A CI(G)S-based thin film for use in a light absorption layer of a solar cell, wherein the CI(G)S-based thin film is manufactured by preparing CI(G)S-based binary nanoparticles; mixing the binary nanoparticles, a solution precursor including a CI(G)S-based element, a solvent and a chelating agent, thus preparing a hybrid slurry; aging the hybrid slurry for 5 to 10 days; subjecting the aged hybrid slurry to non-vacuum coating, thus forming a CI(G)S-based thin film; and subjecting the CI(G)S-based thin film to selenization heat treatment.

15. A solar cell using a CI(G)S-based thin film as a light absorption layer, wherein the CI(G)S-based thin film is manufactured by preparing CI(G)S-based binary nanoparticles; mixing the binary nanoparticles, a solution precursor including a CI(G)S-based element, a solvent and a chelating agent, thus preparing a hybrid slurry; aging the hybrid slurry for 5 to 10 days; subjecting the aged hybrid slurry to non-vacuum coating, thus forming a CI(G)S-based thin film; and
subjecting the CI(G)S-based thin film to selenization heat treatment subjecting.
